(19) United States
(12) Patent Application Publication
(10) Pub. No.: US 2020/0043895 A1
(43) Pub. Date: Feb. 6, 2020

(54) ELECTRONIC SYSTEM PROVIDED WITH A PLURALITY OF INTERCONNECTED ELECTRONIC FUNCTIONS

(71) Applicant: MBDA FRANCE, Le Plessis-Robinson (FR)

(72) Inventor: René Dupre, Le Plessis-Robinson (FR)

(73) Assignee: MBDA FRANCE, Le Plessis-Robinson (FR)

(21) Appl. No.: 16/092,421

(22) PCT Filed: Mar. 23, 2017
(86) PCT No.: PCT/FR2017/000056

§ 371 Date: Oct. 9, 2018

(30) Foreign Application Priority Data
Apr. 12, 2016 (FR) 1600616

(51) Int. Cl. H01L 25/065; H01L 23/13; H01L 23/498; H01L 23/50

(52) U.S. Cl. CPC H01L 25/0657; H01L 23/13; H01L 23/49833; H01L 23/50; H01L 2225/06589; H01L 2225/06568; H01L 2225/06565; H01L 2225/06575; H01L 2225/0651

(57) ABSTRACT

The electronic system includes a connection ring comprising a plurality of alternately conductive and insulating superposed layers, the superposed conductive layers being linked to one another by electrical links forming an interconnect network, said connection ring comprising an inner cavity, the electronic system also including a plurality of electronic functions that are arranged inside the inner cavity of said connection ring over a plurality of levels, with at least one electronic function per level, each of said electronic functions being linked to the connection ring at the level of the inner face of the latter.

The present invention relates to an electronic system provided with a plurality of interconnected electronic functions.

As part of the present invention, the term electronic functions is taken to mean any element (or function) made electronically and being in the form of single components (components in an individual casing or made of silicon (chip or integrated circuit, naked)) and/or in the form of electronic sub-functions themselves using single electronic components.

Currently, the need for integrating electronic functions requires finding technical solutions to concentrate a maximum amount of electronic components in an increasingly restricted volume.

The solutions proposed to do this must not be limiting, in other words, they must be able to respond to the integration, both for individual components and for electronic functions constituted by several components.

In most cases, a specific response is provided for this need. Indeed, manufacturers of electronic components propose solutions of pre-stacked components and put in a standard commercial casing or components put in stackable casings. In these two examples, the manufacturer of components can only provide the space gain solution only for the manufacturer's specific family of components (memories, for example), but it does not offer the possibility of stacking components that the manufacturer has produced in association with components from another manufacturer.

Moreover, more complex solutions for stacking functions, are not normally proposed. “Owner” casing implementation solutions must be resorted to.

The concept of usual “owner” solutions is generally based on the production of a large component capable of being installed by a user onto a support board.

The present invention aims to overcome these disadvantages, by providing an electronic system enabling, in particular, concentrating a maximum amount of interconnected electronic functions in a restricted volume.

According to the invention, the electronic system comprises:
a connection ring comprising a plurality of superposed layers, alternately conductive and insulating, being linked to one another by electrical links and forming an interconnect network, said connection ring comprising an inner cavity; and
a plurality of electronic functions arranged inside the inner cavity of said connection ring on a plurality of levels, with at least one electronic function per level, each of said electronic functions being linked to the connection ring at the level of the inner face of the latter.

The connection ring thus constitutes a three-dimensional interconnection system that can be used to produce electrical connections between different levels of stacked electronic functions.

Thanks to the specific architecture proposed, comprising this connection ring and the electronic functions arranged as mentioned above, a maximum amount of interconnected electronic functions can be concentrated in a restricted volume.

This architecture is different from the usual abovementioned solution, as it is based on the concept which consists of introducing, not a large component, but implementing a three-dimensional interconnect network. The electrical connections between the levels are organised in the ring around the different functions to be linked to one another.

Advantageously, the connection ring in particular has one of the following shapes:
a cylindrical shape;
a parallelepiped shape.

Furthermore, advantageously, in the connection ring, the electrical links between two successive levels, are made via electrically conductive holes, preferably metallic.

Moreover, advantageously, the electronic functions are linked to the connection ring via electrical connections which are connected, on one hand, to the inputs/outputs of the electronic functions and, on the other hand, to metallic tracks situated inside the connection ring. Preferably, an electrical connection comprises at least one of the following elements:
a metal thread;
a flexible printed circuit.

Furthermore, advantageously, the electronic system comprises:
surface connections at least on a lower part of the connection ring; and/or
at least one spacer between two levels of directly successive electronic functions. Preferably, the spacer comprises at least one interconnect circuit.

Moreover, advantageously, the electronic functions arranged over said plurality of levels form a vertical stack, and the electronic system comprises two heat sinks arranged on the two vertically extreme faces, of the vertical stack of electronic functions. Preferably, the electronic system also comprises a heat seal associated with the heat sink.

Furthermore, advantageously, the electronic system comprises two heat sinks arranged, respectively, on the two extreme vertical faces, of the vertical stack of electronic functions.

Moreover, advantageously, the electronic system comprises at least one resin coating arranged in at least one part of the inner cavity of the connection ring.

The present invention also relates to a method for assembling an electronic system such as defined above.

According to the invention, said assembly method comprises at least the following steps:
providing output connections on a connection ring, the connection ring comprising a plurality of superposed layers, alternately conductive and insulating, the superposed conductive layers being linked to one another by electrical links forming an interconnect network, said connection ring comprising an inner cavity;
arranging the connection ring on a base substrate;
successive implementations of different levels of electronic functions, inside the inner cavity of the connection ring, starting with the lower part of the latter, with a connection, level by level, of inputs/outputs with the connection ring.

Moreover, in a specific embodiment, the assembly method comprises, in addition:
a subsequent step of filling with a coating resin at least one empty part of the inner cavity of the connection ring; and/or
at least one step of providing at least one spacer, between two levels of electronic functions, this step being implemented between the two successive implementations of said two levels of electronic functions.

Furthermore, advantageously, the assembly method comprises, in addition, at least one step of providing a heat sink, this step being implemented:
before the successive implementations of different levels of electronic functions, for a heat sink referred to as lower heat sink;
after the successive implementations of different levels of electronic functions, for a heat sink referred to as upper heat sink.

The manner in which the invention can be achieved will be understood with the appended figures. In these figures, identical references mean similar elements. More specifically:

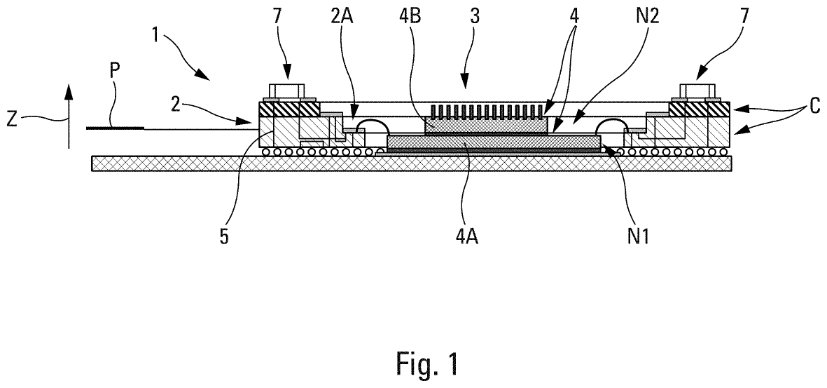

FIG. 1 is a schematic view of a specific embodiment of an electronic system with two levels of functions or interconnections;

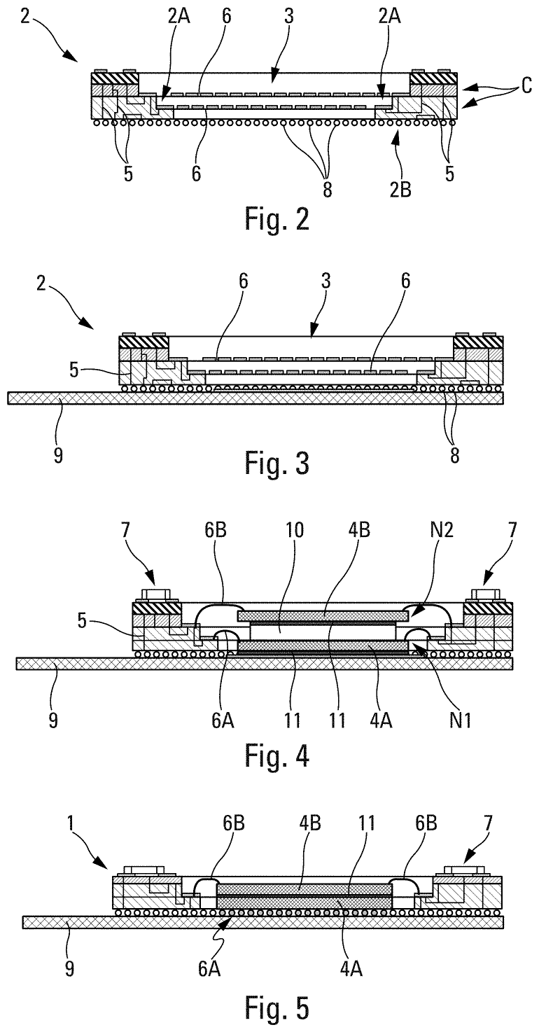

FIG. 2 is a schematic view of a connection ring;

FIG. 3 is a schematic view of a connection ring after being installed on a substrate of use;

FIG. 4 is a schematic view of an electronic system with two levels of interconnections with a spacer referred to as neutral;

FIG. 5 is a schematic view of an electronic system with two levels of interconnections, the lower level being bearing;

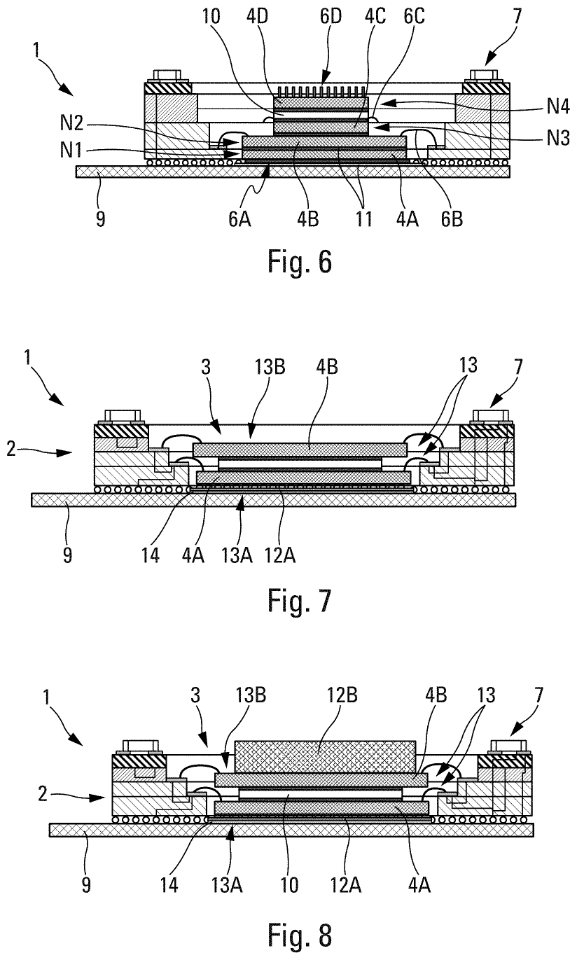

FIG. 6 is a schematic view of an electronic system with four levels of interconnections with a spacer, the lower level being bearing;

FIGS. 7 and 8 are schematic views of an electronic system provided with two levels of functions (or interconnections), respectively with one single heat sink positioned in the lower part, and with two heat sinks positioned respectively in the lower part and in the upper part; and

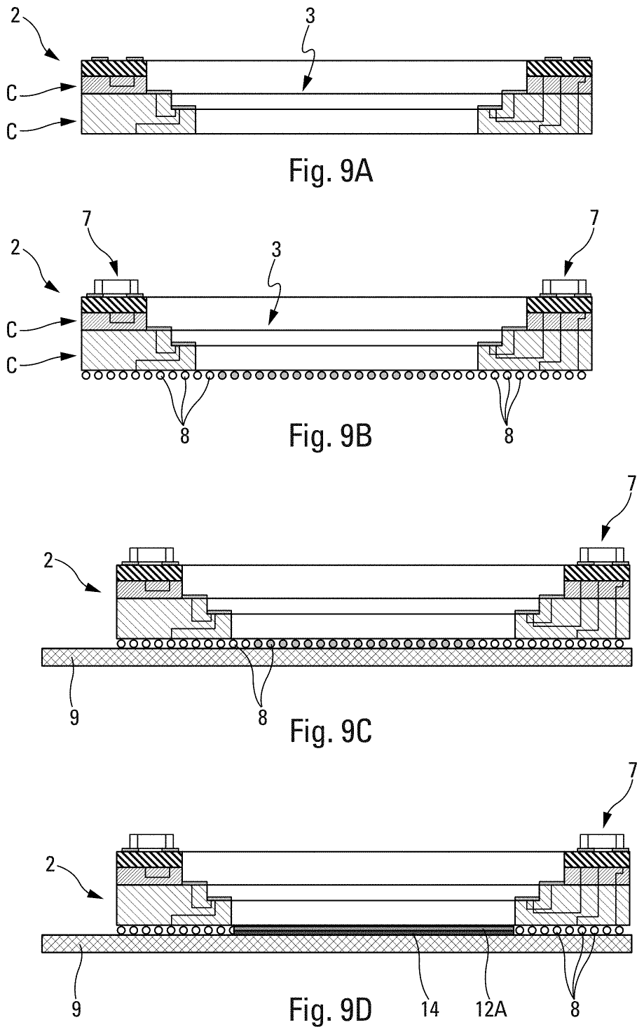

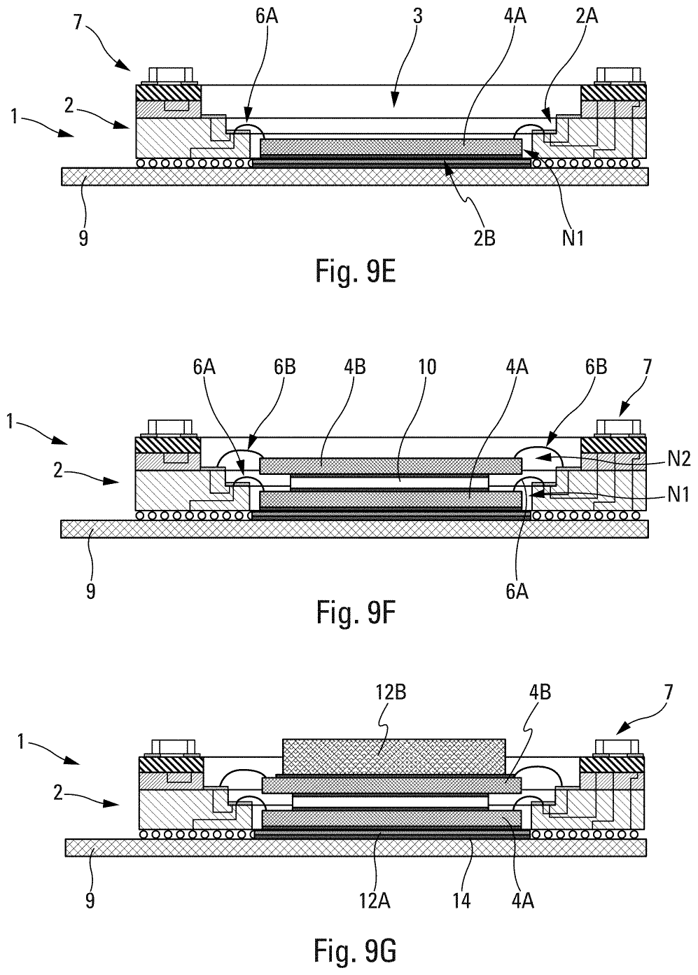

FIGS. 9A to 9G illustrate different successive steps of a method for assembling an electronic system that conforms with a preferred embodiment of the invention, provided with heat sinks.

The electronic system 1, which illustrates the invention and is represented schematically in FIG. 1, comprises:
a connection ring 2 such as represented in FIG. 2. This connection ring 2 comprises a plurality of superposed conductive layers, separated from one another by insulating layers. The superposed conductive layers C are linked to one another by electrical links specified above so as to form an interconnect network. The connection ring 2 comprises an inner cavity 3; and
a plurality of electronic functions 4 arranged inside the inner cavity 3 of the connection ring 2 over a plurality of superposed levels N1, N2, etc., with at least one electronic function per level, namely the function 4A on the level N1 and the function 4B on the level N2 in the example in FIG. 1.

Each of said electronic functions 4 is linked to the connection ring 2 at the level of the annularly inner face 2A of the latter.

The connection ring 2 also comprises a stack of insulating and conductive layers forming a three-dimensional system (or network) of electrical interconnections, which can be used to produce electrical connections between different levels N1, N2, etc., of stacked electronic functions 4.

The stack of layers in the connection ring 2 and the stack of levels N1, N2 of functions, for example, of up to fifteen levels, are produced along a direction Z referred to as vertical, which is orthogonal to a plane P referred to as horizontal, the stacks being positioned therein or parallel thereto.

Thanks to this specific architecture comprising the connection ring 2 and the functions 4 arranged as mentioned above, the electronic system 1 is able to concentrate a maximum amount of interconnected electronic functions 4 in a restricted volume.

The connection ring 2 can, in particular, be of cylindrical shape, or parallelepiped shape, or any other closed curved shape, adapted to the envisaged application. The connection ring 2 is therefore hollowed out in the environment thereof so as to create the inner cylindrical space 3, intended to receive the basic electronic functions which must be interconnected to one another.

The architecture of the electronic system 1 thus comprises a three-dimensional interconnect network, wherein the electrical connections between the levels are organised in the ring around the different functions to be linked to one another.

In the connection ring 2, the electrical links 5 between two successive levels, represented in particular in FIGS. 1 and 2, are made via electrically conductive holes, preferably metallic. Consequently, the interconnections between the different levels of the connection ring 2 (inner electrical links) are made in the vertical plane Z (inside the side walls of the connection ring 2) by way of metallic holes. These bondings can be of different types (copper, silver, palladium, gold, carbon, etc.).

Moreover, the electronic functions 4 are linked to the connection ring 2 via the electrical links 6 (represented, in particular, in FIGS. 2 and 3) which are connected, on one hand, to the inputs/outputs of the electronic functions 4, and on the other hand, to the metallic tracks situated inside the inner cavity 3 of the connection ring 2 and arranged according to needs.

The connection of the electronic functions 4 is therefore made on the inner face 2A of the connection ring 2, by way of electrical links 6 which can be provided in the form of electrical connections such as metal threads of different types, flexible printed circuits or any other form likely to ensure an electrical connection between the function 4 considered and the connection ring 2.

The electrical links, inside the electronic system 1, are thus made in a plane parallel to the plane P by metallic-type conductive links (links 6), and between planes, by conductive holes (links 5), such as metallic holes ensuring, in the vertical direction Z, connections between the levels.

If necessary, the connection ring 2 can also receive passive type electronic components 7 (resistances, condensers, coils), as represented in particular in FIGS. 1 and 4 to 8. These passive components 7 can be decoupling components (condenser) or adaptation components (resistances: “pullup”, “pulldown”, matching).

These passive components 7 can be returned to the surface (as represented in FIGS. 1 and 4 to 8), or be integrated inside the connection ring 2.

Moreover, surface connections 8 are provided at the lower part 2B (in the direction Z), in other words, at the base of the connection ring 2, as represented in FIG. 2. They are intended to produce electrical links between the connection ring 2 and a substrate 9 of use (or base substrate), such as a board, on which is mounted the electrical system 1, as shown in FIG. 3.

Furthermore, in a specific embodiment, the electronic system 1 comprises at least one spacer 10 (or spacer plate) which is arranged between two levels N1 and N2 of electronic functions 4A and 4B, directly successive, as illustrated in FIG. 4. The electronic functions 4A and 4B are fixed by glue seals 11. Such a spacer 10 aims to bring the functions 4B of the level N2 to the same height along the direction Z as the conductive layer associated with this level of the connection ring 2, to be able to produce connections between the connection ring 2 and the function 4B of the level N2 considered in a plane parallel to the plane P.

As an illustration, FIGS. 4 and 6 show a spacer 10 between two levels, namely between the levels N1 and N2 in FIG. 4, and between the levels N3 and N4 (comprising the electronic functions 4C and 4D) in FIG. 6. In FIG. 6, the inner electrical connections 6A, 6B, 6C and 6D have also been represented.

In a simplified embodiment, this spacer 10 is simply a mechanical spacer (neutral spacer), the purpose of which is only to produce an adjustment of the vertical position in order to enable the production of output connections of the electronic function.

However, in a specific embodiment, the spacer 10 can also comprise an interconnect circuit between two adjacent levels. In this case, the spacer is referred to as active.

Moreover, in a preferred embodiment, the electronic system 1 comprises at least one heat sink 12A and 12B which is arranged on a face, vertically at the far end (along the axis Z) from the vertical stack 13 of electronic functions 4A and 4B, as shown in FIGS. 7 and 8.

This heat sink 12A, 12B generates a heat sinkage that brings to the surface the heat emitted by the electronic functions 4A, 4B integrated in the middle of the connection ring 2 (in the inner cavity 3).

Preferably, the electronic functions that produce the most heat are arranged closest to this heat sink 12A, 12B.

Adding this heat sink function also allows the use of any type of spacer, active or neutral.

Preferably, the electronic system 1 also comprises a heat seal 14 associated with the heat sink 12A, as shown in FIGS. 7 and 8.

FIGS. 7 and 8 illustrate examples of an electronic system 1 that requires heat sinkage. This heat sinkage can be produced on one single face 13A (FIG. 7), or on the two faces 13A and 13B, vertically extreme from the vertical stack 13 of electronic functions 4A and 4B.

Moreover, the electronic function 1 can comprise at least one resin coating (not shown) which is introduced into the empty part of the inner cavity 3 of the connection ring 2. This coating, in particular, makes the electronic system 1 more reliable.

The electronic system 1, such as defined above, can be assembled by way of an assembly method specified below in reference to FIGS. 9A to 9G.

This assembly method comprises at least the following steps:
a step of providing the connection ring 2, such as that represented in FIG. 9A, passive components 7 and inputs/outputs 8 of the connection ring 2, as shown in FIG. 9B. The connection ring 2 comprises, as indicated above, a plurality of superposed layers, alternately conductive and insulating. The superposed conductive layers C are linked to one another by electrical links by forming an interconnect network. The connection ring 2 also comprises an inner cavity 3;
a step of arranging the connection ring 2 on a base substrate 9, as represented in FIG. 9C;
a step of providing a heat drain 13A referred to as lower heat drain, via a heat seal 14, on the base substrate 9, as represented in FIG. 9D;
successive steps of implementing different levels N1, N2 of electronic functions, inside the inner cavity 3 of the connection ring 2. To do this, the lower part 2B of the connection ring 2, as shown, is started with, for the electronic function 4A of the first level N1 in FIG. 9E, and a connection is made, level by level, of inputs/outputs of the electronic functions with the connection ring 2;
at least one step of implementing at least one spacer 10, between two successive levels N1 and N2 of electronic functions 4A and 4B. Such a step is implemented between the two successive implementations of said two levels N1 and N2. It is followed by a step of providing the electronic function 4B at the second level N2 as shown in FIG. 9F; and
a step of implementing a heat sink 12B referred to as upper heat sink, via an assembly seal (glue), as shown in FIG. 9G.

Moreover, in a specific embodiment, the assembly method can comprise, in addition, a step of filling with a coating resin (not shown) at least one empty part of the inner cavity 3 of the connection ring 2.

The system 1, such as defined above, thus has, in particular, the following advantages:
it enables the use for electronic functions of all possible types of components, encapsulated or not, and in particular, passive components 7 and/or active components 4A to 4D, which can be provided by different manufacturers;
it produces (via the connection ring 2) the electrical interconnection of the electronic functions 4A to 4D, stacked and positioned at different levels N1 to N4;
it can be used with the main usual substrates 9, used in the production of electronic functions (organic or mineral materials);
it has the capacity, if necessary, to integrate one or more heat sinks 12A, 12B;
it protects electrical links between levels against parasitic reading attempts. Indeed, these links are not accessible, unlike certain technical solutions which expose connections between peripheral levels, constituting a potential source of espionage of the provided function; and
the central cavity 3 of the connection ring 2 can be protected, by being filled with coating resin.

1. An electronic system provided with a plurality of interconnected electronic functions, comprising:
a connection ring comprising a plurality of superposed layers, alternately conductive and insulating, the superposed conductive layers being linked to one another by electrical links and forming an interconnect network, said connection ring comprising an inner cavity; and
a plurality of electronic functions arranged inside the inner cavity of said connection ring on a plurality of levels, with at least one electronic function per level, each of said electronic functions being linked to the connection ring at the level of an inner face of the latter.

2. The electronic system according to claim 1, wherein the connection ring has one of the following shapes:
a cylindrical shape; or
a parallelepiped shape.

3. The electronic system according to claim 1, wherein, in the connection ring, the electrical links between two successive levels are made via electrically conductive holes.

4. The electronic system according to claim 1, wherein the electronic functions are linked to the connection ring via electrical connections which are connected, on one hand, to inputs/outputs of the electronic functions, and on the other hand, to metallic tracks situated inside the connection ring.

5. The electronic system according to claim 1, comprising surface connections at least on a lower part of the connection ring.

6. The electronic system according to claim 1, comprising at least one spacer between two levels of directly successive electronic functions.

7. The electronic system according to claim 6, wherein the spacer comprises at least one interconnect circuit.

8. The electronic system according to claim 1, wherein the electronic functions arranged over said plurality of levels form a vertical stack, and wherein the electronic system comprises at least one heat sink arranged on a face, vertically at the far end from the vertical stack of electronic functions.

9. The electronic system according to claim 8, comprising a heat seal associated with the heat sink.

10. The electronic system according to claim 8, comprising two heat sinks arranged, respectively, on the two faces, vertically at the far end from the vertical stack of electronic functions.

11. The electronic system according to claim 1, comprising at least one resin coating arranged in at least one part of the inner cavity of the connection ring.

12. A method for assembling an electronic system, comprising at least the following steps:
providing output connections on a connection ring, the connection ring comprising a plurality of superposed layers, alternately conductive and insulating, the superposed conductive layers being linked to one another by electrical links by forming an interconnect network, said connection ring comprising an inner cavity;
arranging the connection ring on a base substrate; and
successive provisions of different levels of electronic functions, inside the inner cavity of the connection ring, starting with the lower part of the latter, with a connection, level by level, of inputs/outputs with the connection ring.

13. A method according to claim 12, comprising filling with a coating resin of at least one empty part of the inner cavity of the connection ring.

14. A method according to claim 12, comprising providing a heat sink:
before the successive provisions of different levels of electronic functions; and
after the successive provisions of different levels of electronic functions.

15. A method according to claim 12, comprising providing at least one spacer between two levels of electronic functions, wherein the at least one spacer is provided between the two successive provisions of said two levels of electronic functions.
